(19) United States
(12) Patent Application Publication
(10) Pub. No.: US 2023/0062660 A1
(43) Pub. Date: Mar. 2, 2023

(54) TEMPERATURE DEPENDENT ELECTRONIC COMPONENT HEATING SYSTEM

(71) Applicant: AMETEK, INC., Berwyn, PA (US)

(72) Inventors: Brian Hoden, Albuquerque, NM (US); Joo-Han Kim, Huntsville, AL (US); James Sweeney, Berwyn, PA (US); John Torgenson, Berwyn, PA (US)

(73) Assignee: AMETEK, INC., BERWYN, PA (US)

(21) Appl. No.: 17/893,680

(22) Filed: Aug. 23, 2022

Related U.S. Application Data
(60) Provisional application No. 63/237,812, filed on Aug. 27, 2021.

(51) Int. Cl. H01L 23/34

(52) U.S. Cl. CPC H01L 23/345

(57) ABSTRACT

An electronics assembly having a substrate, a heat-conductive body spaced from the substrate, a temperature dependent electronic component mounted on the substrate, and a heating element in thermal contact between the temperature dependent electronic component and the heat-conductive body. Methods of making and using an electronics assembly are also provided.

This application claims the benefit of and priority to U.S. Provisional Application Ser. No. 63/237,812, filed Aug. 27, 2021, which is incorporated by reference herein.

### BACKGROUND

Various electronic components are unable to operate, or have limited operating capacity, below certain temperatures. Such devices are referred to herein as “temperature dependent electronic components” or by the term “TDEC.” TDECs are frequently incorporated into an electronics assembly having other components that do not have temperature dependent characteristics, or are able to operate at temperatures that are lower than those of a particular TDEC. In this situation, it may be necessary to wait until the entire electronics assembly is at the minimum operating temperature of the most temperature-sensitive TDEC. Alternatively the TDEC may be isolated from the remainder of the electronics assembly and heated separately, or positioned where it is not subjected to the relatively cold environment of the remainder of the electronics assembly.

TDECs are sometimes heated to their operating temperature using a convective or conductive heat flow path to a heat source. For example a TDEC and the remainder of the electronics assembly may be heated by a flow of air, with or without the assistance of finned heat sinks and active air movement using a fan or the like. In other cases, the TDEC and remainder of the electronics assembly may be placed in contact with a conductive heating element, such as a metal chassis or frame that holds the printed circuit board and conveys heat from a remote source to the electronics assembly. A TDEC also may be more directly heated by attaching a heat sink, such as a thin aluminum radiator, directly to the TDEC, or by placing the TDEC into contact with a convective object to receive heat from a remote source.

The inventors have determined that conventional methods for heating a TDEC can be relatively inefficient, and may not be suitable to satisfy desired start up times. This is particularly true in the context of vehicles and equipment being operated in arctic or other cold-weather environments, in which the ambient storage temperature of the electronics assembly may be −40° C., or even as low as −54° C. In such cases, heating the TDEC can take a very long time, leading to inconveniences, and, in the case of military applications, a potential operational disadvantage.

Thus, the inventors have determined that the state of the art still needs to be improved.

### SUMMARY

In a first exemplary aspect, there is provided an electronics assembly comprising: a substrate; a heat-conductive body spaced from the substrate; a temperature dependent electronic component mounted on the substrate; and a heating element in thermal contact between the temperature dependent electronic component and the heat-conductive body.

In a second exemplary aspect, there is provided a method of operating an electronics assembly comprising a substrate, a heat-conductive body, a temperature dependent electronic component mounted on the substrate, and a heating element in thermal contact between the temperature dependent electronic component and the heat-conductive body. The method comprises: measuring a first temperature value representing a first operating temperature of the temperature dependent electronic component; determining that the first temperature value does not exceed a first reference temperature value; passing an electric current through the heating element to generate a first quantity of thermal energy; passing a first portion of the first quantity of thermal energy from the heating element to the temperature dependent electronic component; measuring a second temperature value representing a second operating temperature of the temperature dependent electronic component; determining that the second temperature value is not below the first reference temperature value; and terminating passing the electric current through the heating element.

In a third exemplary aspect, there is provided a method for manufacturing an electronics assembly, the method comprising providing a substrate comprising a temperature dependent electronic component attached to the substrate; attaching a heating element to the temperature dependent electronic component by a first thermally conductive path; and attaching a heat-conductive body to the heating element by a second thermally conductive path.

### BRIEF DESCRIPTION OF THE DRAWINGS

Exemplary embodiments will now be described with reference to the attached Figures in which like references refer to like features.

FIG. 1 is a schematic side view of a first example of an electronics assembly.

FIG. 2 is a schematic isometric view of a second example of an electronics assembly.

FIG. 3 is a schematic side view of a third example of an electronics assembly.

FIG. 4 is a schematic side view of a fourth example of an electronics assembly.

FIG. 5 is a schematic plan view of a fifth example of an electronics assembly.

FIG. 6 is a schematic view of a sixth example of an electronics assembly.

FIG. 7 is a schematic view of a seventh example of an electronics assembly.

FIG. 8 is a schematic view of an eighth example of an electronics assembly.

FIG. 9 is a schematic view of a ninth example of an electronics assembly.

FIG. 10 is a schematic view of a tenth example of an electronics assembly.

### DETAILED DESCRIPTION OF EXEMPLARY EMBODIMENTS

Various exemplary embodiments are described herein to illuminate the scope and meaning of the appended claims. However, these embodiments are all intended to be non-limiting examples of the claimed subject matter. Also, it will be understood that features described in relation to an embodiment may also be incorporated into other embodiments where such would still yield an operational mechanism or process, as will be appreciated by persons of ordinary skill in the art.

Throughout this description and the appended claims, words used in the singular will be understood to include the plural, and vice-versa (e.g., a claim reciting a “a” feature is not limited to structures having only one such feature, unless expressly qualified as being “a single” feature, or using similar limiting language). Also, terms of position and location relative to a global reference frame, such as “above” and “below,” are used to assist with describing the embodiments, however such terms are not intended to limit the embodiments or claims to structures having a particular global orientation. This description and the appended claims also refer to various physical measurements and dimensional properties. It will be understood that essentially all measurements are subject to ranges of error as a result of environmental conditions and typical variations in instrument precision, and all manufactured parts are subject to variations in dimension as a result of typical manufacturing tolerances. Thus, all dimension and measurements used in herein will be understood to be approximate, but within a range of typical variations, as will be understood by persons of ordinary skill in the art in view of the disclosure herein.

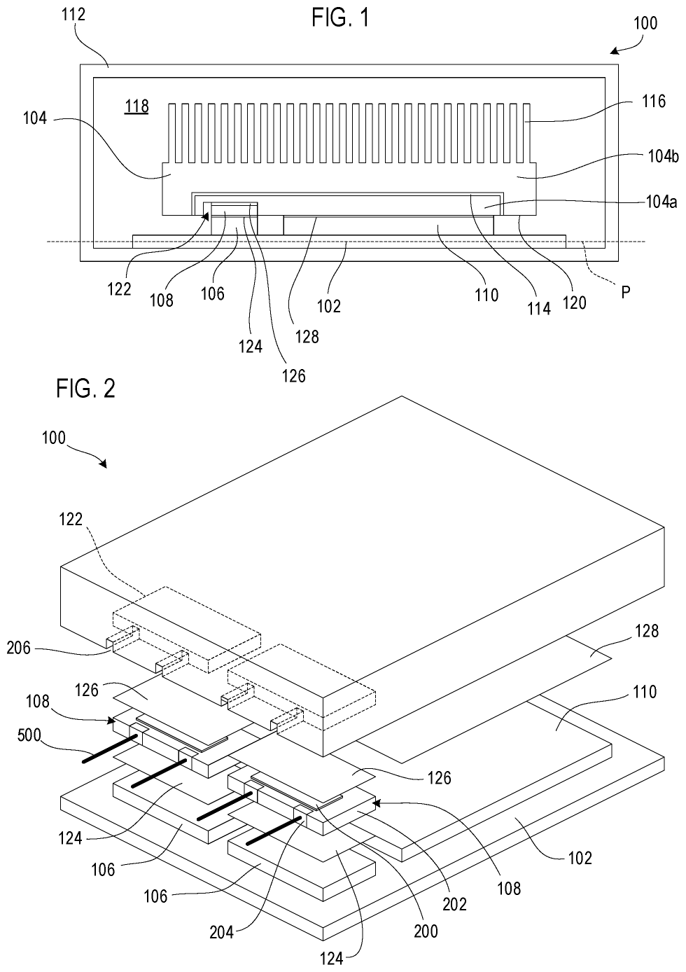

Referring now to FIG. 1, a first exemplary embodiment provides an electronics assembly 100 comprising a substrate 102, a heat-conductive body 104 spaced from the substrate, a temperature dependent electronic component (“TDEC”) 106 mounted on the substrate 100, and a heating element 108 in thermal contact between the temperature dependent electronic component and the heat-conductive body. The assembly 100 also includes an integrated circuit 110 mounted on the substrate 102 and in thermal contact with the heat-conductive body 104. The electronics assembly 100 may be mounted directly or indirectly to a housing 112 or other structure to facilitate integration of the electronics assembly 100 into equipment, such as a computer component frame, aircraft or other vehicle, of the like.

The substrate 102 extends along a plane P, with the TDEC 106 and integrated circuit 110 extending on one side of the substrate 102. The substrate 102 may comprise a printed circuit board, or any other suitable structure for holding the electrical components. The substrate 102 also may be mounted on an underlying structure, such as an underlying printed circuit board. Any suitable connection can be used to hold the substrate 102 to the housing 112, as will be appreciated by those skilled in the art.

The TDEC 106 may comprise any electronics component that is unable to operate, or has limited operating capacity, below a certain temperature, and more specifically below the minimum startup temperature of the electronics assembly 100. For example, if the electronics assembly 100 is required to begin operation at a temperature of 0° C. (i.e., Celsius), the minimum startup temperature would be 0° C., and any electronic components in the electronics assembly 100 that cannot operate at this temperature would be classified as a TDEC. Those components that can operate at the startup temperature would not be classified as a TDEC.

Examples of TDECs include computer memory, crystal oscillators and Infiniband/Ethernet interconnect semiconductors/devices, all of which can have relatively high minimum operating temperatures as compared to other electronics components, such as integrated circuits, that interface with those devices. The illustration of the TDEC 106 in the drawings is intended to schematically represent all of these different devices.

A particular example of a TDEC is high bandwidth memory used in conjunction with a field programmable gate array, such the VIRTEX ULTRASCALE+VU19P field programmable gate array (“FPGA”) with high bandwidth memory (“HBM”), available from XILINX of San Jose, Calif. Such high bandwidth memory may be required to communicate with the field programmable gate array at 230 gigabits/second, or higher (e.g., terabit-class rates). In this device, the field programmable gate array can operate at temperatures below −20° C. (and even as low as −40° C. or below), but the high bandwidth memory cannot, making the high bandwidth memory a TDEC as compared to the field programmable gate array. Furthermore, in some cases a memory, such as a high bandwidth memory may not operable at its full capacity, or reliably operable, until the temperature reaches 0° C. or a similar threshold. As one example, the Intel® Stratix® 10 MX field programmable gate array is offered with a high bandwidth memory, but the interface to the high bandwidth memory is not operable until the temperature reaches 0° C. Thus, the high bandwidth memory must be heated significantly before it achieves full functionality, which severely limits the operation of the entire device in colder temperatures.

Similarly, crystal oscillators and Infiniband/Ethernet interconnect semiconductors/devices typically cannot function at temperatures at or below −40° C. For example, the AMB3B crystal oscillator from Abracon has a minimum operating temperature of −10° C. and the ABS07 crystal oscillator, also from Abracon, has a minimum operating temperature of −40° C. but with certain operational constraints that render it unusable. Similarly, the ConnectX-3® Virtual Protocol Interconnect MT27518 Dual 10 GB Ethernet/Infiniband semiconductor (generically, an Infiniband/Ethernet interconnect semiconductor/device) from Mellanox Technologies can have a minimum operating temperature of −40° C., but might be used with an integrated circuit having a lower minimum operating temperature. As another example, the 82580EB/82580DB Gigabit Ethernet controller from Intel® has a minimum operating temperature of −10° C., and a cooling requirement of about 4 Watts. Thus, such devices typically are or can be TDECs as compared to their associated integrated circuits or other electronic components.

The TDEC 106 may comprise any of the foregoing devices (e.g., a memory, a high bandwidth memory, a crystal oscillator, or an Infiniband/Ethernet interconnect semiconductor/device, or other devices having similar operating temperature constraints as compared to the associated electronic components.

The integrated circuit 110 may comprise any kind of circuit. For example, the integrated circuit 106 may be a field programmable gate array, a computer processing unit, a graphics processing unit, or an Infiniband/Ethernet interconnect semiconductor/device processing unit. The illustration of the integrated circuit 110 in the drawings is intended to schematically represent all of these different devices. In a typical application, the integrated circuit 110 is electrically connected to the integrated circuit 110. For example, a field programmable gate array may be connected to a high bandwidth memory by high bandwidth communication pathways. However, an electrical communication path between the integrated circuit 110 and the TDEC 106 is not strictly required in all cases.

When the TDEC 106 and integrated circuit 110 are operation, one or both can generate a significant amount of heat, which must be removed to ensure continued operation. The heat-conductive body 104 operates to remove the operating heat. More specifically, operating heat from the integrated circuit 110 and TDEC 106 is passed by conduction to the heat-conductive body 104, and then removed from the heat-conductive body 104 by conduction and/or convection (radiation transfer is also possible, but likely to be minimal compared to other heat transfer mechanisms). Convection heat transfer may be by natural convection, forced convection or combination of both.

The heat-conductive body 104 is spaced from the substrate 102, and at least a portion of the heat-conductive may extend parallel to the plane P of the substrate 102. In the example of FIG. 1, the heat-conductive body 104 comprises an assembly of a metal plate 104a and a heat sink 104b. The heat sink 104b is joined to the metal plate 104a, and at least part of the heat sink 104b may extend from the metal plate 104a away from the substrate 102. The metal plate 104a comprises copper or another material having a relatively high thermal conductivity. For example, the metal plate 104a may comprise copper or a copper alloy having a thermal conductivity coefficient of approximately 400 Watts per meter-Kelvin (all thermal conductivity coefficient values herein are considered at a temperature of 0° C.). In contrast, the heat sink 104b may have a relatively low thermal conductivity, as compared to the metal plate 104a. For example, the heat sink 104b may comprise a conventional aluminum alloy (e.g., 6063 alloy) having a thermal conductivity coefficient of approximately 200-250 Watts per meter-Kelvin.

This arrangement of a metal plate 104a and heat sink 104b has been found to provide an efficient mechanism to rapidly distribute operating heat away from the integrated circuit 110 and TDEC 106, while still taking advantage of the lower cost and machinability (particularly the ability to extrude into complex shapes) of an aluminum material as the heat sink 104b. In use, the high-conductivity metal plate 104a increases local heat removal at the electronic components, and helps rapidly distribute the heat to the full body of the heat sink 104b. This arrangement also avoids the need to perform significant machining operations on the metal plate 104a, which can have a simple rectangular shape.

The metal plate 104a may be secured to the heat sink 104b by any suitable connection. In the shown example, the metal plate 104a is embedded in a recess within the heat sink 104b. A layer of thermal gel or thermal grease 114 may be provided between the metal plate 104a and the heat sink 104b to improve heat transfer between them. In other embodiments, the metal plate 104a may not be located in a recess in the heat sink 104b, or other attachments may be used. For example, the metal plate 104a may be fixed to a flat face of the heat sink 104b by screws, rivets or the like. Other alternatives and variations will be apparent to persons of ordinary skill in the art in view of the present disclosure.

While embodiments having a heat-conductive body 104 formed by a metal plate 104a and heat sink 104b can have advantages, this arrangement is not strictly required (see, e.g., the following embodiments).

The heat-conductive body 104 may include fins 116, ribs, surface treatments, or other shapes or features to enhance heat dissipation, as known in the art. The heat sink 104b also may be located in a passage 118 formed inside the housing 112, through which a fluid (e.g. air) is passed to enhance heat dissipation. Also, as explained below, the heat-conductive body may be cooled by a liquid via internal or external cooling passages.

The problem of differential minimum operating temperatures between the TDEC 106 and the integrated circuit 110 is addressed by heating the TDEC 106 with a heating element 108. The heating element 108 preferably comprises a resistor, and more particularly a resistor that is able to adequately heat the TDEC 106 to the operating temperature, while also permitting adequate heat dissipation from the TDEC 106 to the heat-conductive body 104 when the TDEC 106 is operating. In addition, when the electronics assembly 100 includes an integrated circuit 110 or other components in contact with the heat-conductive body 104, the heating element 108 must be configured such that it does not excessively heat the other components during startup.

It has been found that certain thick film chip resistors are suitable for use as a heating element 108 in the electronics assembly 100. Referring now also to FIG. 2, in general terms, a thick film chip resistor comprises a thick resistive film layer 200 (e.g., a mixture of metal oxides) printed on or applied to a ceramic substrate 202. Contacts 204 are provided on the film layer 200 and/or substrate 202 to connect with a power supply. A large variety of thick film chip resistors are available, but many are not suitable for use in an electronics assembly 100 having demanding requirements to heat a TDEC 106 to the desired operating temperature within the desired time, while still allowing proper heat dissipation from the TDEC 106 in use.

It has been found that at least two thick film chip resistors are suitable as a heating element 108 for high-demand electronics assemblies 100. First, the heating element 108 may comprise a thick film chip resistor comprising a beryllium oxide substrate 202 having (for example) a thermal conductivity coefficient of at least about 250 Watts per meter-Kelvin. Second, the heating element 108 may comprise a thick film chip resistor comprising an aluminum nitride substrate 202 having (for example) a thermal conductivity coefficient of at least about 180 Watts per meter-Kelvin. In either case, the thick film chip resistor may have high-conductivity contacts, 204, such as gold plated beryllium copper contacts, to help ensure efficient operating performance. A further advantage of thick film chip resistors is that they are electrically isolative, and thus do not pass electrical current from the TDEC 106 to the heat-conductive body 104. This helps avoid short-circuits, and improves radio frequency isolation.

These examples of thick film chip resistors have been identified as being suitable for certain high-demand electronics assemblies 100. For example, in one case, the electronics assembly 100 has an integrated circuit 110 in the form of a field programmable gate array, a TDEC 106 in the form of a high bandwidth memory, and a service requirement to reach the desired operating temperature of 0° C. from a storage temperature of −40° C. within 120 seconds. This example is referred to as “Example 1” in the remaining description. In Example 1, is has been determined that the time-to-operation requirement can be satisfied by using a heating element 108 comprising a thick film chip resistor having a heat output sufficient to heat the TDEC 106 at a rate of at least 20° C. per minute, and a high thermal conductivity coefficient (e.g., at least 180 to 250 Watts per meter-Kelvin) to permit sufficient heat dissipation though the heating element 108 during operation.

The heating element 108 may be configured to have the desired heating rate by proper selection of the heating element 108 heat output, and the heat conduction path between the heating element 108 and the TDEC 106, as can be determined using conventional calculations. However, it may be necessary in some cases to ensure that the operation of the heating element 108 does not interfere with the control of other thermal conditions within the electronics assembly 100. For example, excessive heat input can cause an nearby integrated circuit 110 to exceed its rated temperature. Thus, in some embodiments, the heating element 108 is selected to provide the desired heat output to heat the TDEC 106 at the desired rate, but does not negatively affect the thermal balance of the remainder of the electronics assembly 100.

In the case of Example 1, described above, the heating element 108 may comprise a thick film chip resistor with a beryllium oxide substrate 202, which is sandwiched between the TDEC 106 and the heat-conductive body 104. A lower face of the heating element 108 extends parallel to the plane P of the substrate 102, and has a square or rectangular shape that approximately matches the shape of the adjacent face of the TDEC 106. In this case, it is expected that an adequate heating rate can be achieved, without adversely affecting the remaining thermal balance of the electronics assembly 100, by forming the heating element 108 with a lower surface area, as measured parallel to the plane P, of 0.2 square inches or less, and a thickness, perpendicular to the plane P, of 0.2 inches or less. More preferably, the lower surface's area is 0.1 square inches or less, and the thickness is 0.1 inches or less. Other alternatives and variations will be apparent to persons of ordinary skill in the art in view of the present disclosure and in consideration of the operating requirements for other applications.

As noted above, the heat-conductive body 104 is provided to remove heat from the electronic components during operation of the electronics assembly 100. Thus, a thermal path is provided form the TDEC 106 to the heat-conductive body 104. In the example of FIG. 1, the metal plate 104a portion of the heat-conductive body 104 is most proximal to the TDEC 106, and so the thermal cooling path extends form the TDEC 106, through the heating element 108, and into the metal plate 104a. In other cases, the metal plate 104a may be omitted, or the heat sink 104b portion of the heat-conductive body 104 may be most proximal to the TDEC 106 to provide an alternative cooling heat flow path.

The heat-conductive body 104 may have any suitable shape to address the cooling requirements of the specific application. In the example of FIG. 1, the heat-conductive body 104 is configured to generally follow the topography of the underlying electronic components, and allow space for the heating element 108. In this case, the heat-conductive body 104 has a lower surface 120 facing the substrate 102, and a recess 122 extending away from the substrate 102 and into the surface 120. The heating element 108 is mounted within the recess 120 and the integrated circuit 110 is positioned adjacent to the surface 120. Thus, the heat-conductive body 104 can conform to components at different distances from the substrate 102. In other cases, the recess 122 may be a step at one end of the heat-conductive body 104, or other shapes may be used.

In the particular case of Example 1, the TDEC 106 and integrated circuit 110 may be provided on the substrate 102 as an assembly, with the TDEC 106 and integrated circuit 110 having respective flat upper surfaces that lie in a common plane. In this case, the heat-conductive body 104 may have a flat lower surface 120, and the recess 122 may be dimensioned such that the lower surface of the heating element 108 lies in the plane of the flat lower surface 120. Thus, the heating element 108 can be assembled to the heat-conductive body 104 to form a generally continuous flat lower surface 120. This facilitates simple and effective assembly onto the upper surfaces of the TDEC 106 and integrated circuit 110.

It will be understood from the foregoing that the electronics assembly 100 has various thermal interfaces. In particular, there is a first thermal interface 124 between the TDEC and the heating element 108, a second thermal interface 126 between the heating element 108 and the heat-conductive body 104, and a third thermal interface 128 between the integrated circuit 110 and the heat-conductive body 104. Each thermal interface 124, 126, 128 may comprise a direct attachment between the parts, but it is more preferred for the thermal interfaces 124, 126, 128 to include a thermally-conductive intermediate material.

In the case of the first thermal interface 124 and the third thermal interface 128, it is preferred to provide a relatively thin and highly-conductive thermal path between the parts, to ensure a high level of heat transfer under all operating conditions. Thus, the first thermal interface 124 and third thermal interface 128 may comprise a thermal grease, a thermal gel, or a thermally-conductive epoxy. An example of a thermal grease is Henkel TIC 4000, an example of a thermal gel is Henkel LIQUI-FORM 3500, and an example of a thermally-conductive epoxy is Loctite Ablestick 2151. All of the foregoing are available from Henkel Corporation of Bridgewater N.J.

As for the second thermal interface 126, a thermal grease, thermal gel or thermally-conductive epoxy (such as those described above) also may be used. However, in some cases it may be desirable to provide an interface material that allows for relative movement of displacement of the parts. For example, the second thermal interface 126 may comprise a thermal gap material having elastic properties to expand and contract, to thereby account for and fill gaps that might otherwise be caused by manufacturing tolerances and thermal expansion and contraction between the parts. An example of a thermal gap material is Henkel Gap Pad 2000540, available from Henkel Corporation of Bridgewater N.J.

It may be possible, in some applications, for a thermal gap material to be used at the first and third thermal interfaces 124, 128, but those interfaces are expected in most cases to have relatively greater importance to ensure proper and rapid heat transfer than the second thermal interface 126.

The heating element 108 may be operated using any suitable control system. In general, the control system operates by activating the heating element 108 to heat the TDEC 106, then terminating operation of the heating element 108 when the desired temperature is reached. The control system can operate using any suitable logical algorithm and input. For example, the control system may use proportional integral (PI) controls, or proportional integral derivative (PID) controls, or the like. The control system may be incorporated into the TDEC 106, integrated circuit 110, or a separate component provided on the substrate 102 or elsewhere.

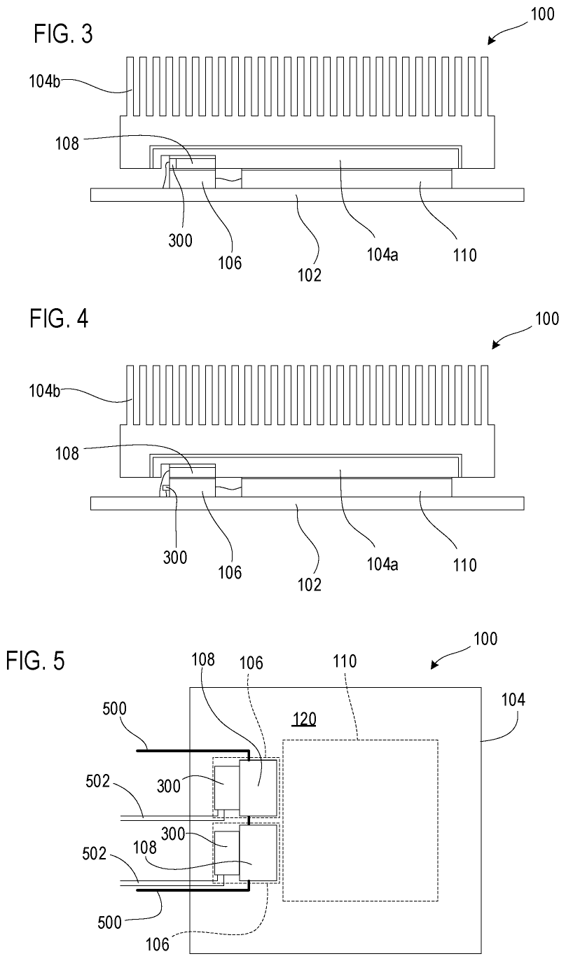

In one example, the control system may receive input from one or more temperature sensors that are positioned or configured to provide an output temperature value that represents the operating temperature of the TDEC 106. Details of exemplary temperature sensors and their locations are described in relation to FIGS. 3-5.

FIGS. 3 and 4 show an electronics assembly 100 substantially as described in relation to FIGS. 1 and 2, with the addition of a temperature sensor 300. The temperature sensor may comprise any suitable device for measuring temperature, such as a resistance temperature detector (RTD) or the like. An example of a RTD is the Vishay PTS08080113100RP100 from Vishay Americas of Shelton Conn. Such devices are known in the art and need not be described in more detail herein.

In FIG. 3, the temperature sensor 300 is positioned in the recess 122 with the heating element 108. This location is expected to facilitate assembly of the temperature sensor 300 into the electronics assembly 102 in a simple and effective manner. The temperature sensor 300 may be configured to determine a temperature at the TDEC 106, at the heating element 108, or at a combination of the components. For example, the temperature sensor 300 may be in thermal communication with the TDEC 106 via the first thermal interface 124, and thermally isolated from the heating element 108 by an insulating material (not shown) to provide a relatively accurate measurement of the operating temperature of the TDEC 106. In this case, the measured temperature value is a direct representative value of the operating temperature of the TDEC 106.

As another example, the temperature sensor 300 may receive thermal energy from both the TDEC 106 and the heating element 108, resulting in measuring a temperature value that is not exactly equal to the operating temperature of either component. However, this temperature value can be used as an indirect representative value of the operating temperature of the TDEC 106, either by developing an appropriate mathematical relationship based on the physical model, or by performing empirical studies to determine how the temperature value at the temperature sensor 300 relates to the actual TDEC operating temperature.

As another example, the temperature sensor 300 may be configured to determine the operating temperature of the heating element 108, which can also be correlated to the operating temperature of the TDEC 106, as described above, to provide an indirect representative value of the operating temperature of the TDEC 106.

Other alternatives and variations will be apparent to persons of ordinary skill in the art in view of the present disclosure. For example, in some cases, where more precise temperature control is not required, the temperature value at the temperature sensor 300 may simply be taken as the TDEC operating temperature, even if it is known that the measured temperature is not the same as the actual operating temperature.

The temperature sensor 300 also may be located outside the recess 122. For example, it may be secured directly to the TDEC 106, such as shown in FIG. 4. It is also contemplated that that the temperature sensor 300 may be integrated into the heating element 108 or the TDEC 106. Other alternatives and variations will be apparent to persons of ordinary skill in the art in view of the present disclosure.

FIG. 5 schematically illustrates a bottom view of a heat-conductive body 104 assembled together with two heating elements 108 and two temperature sensors 300. The two heating elements 108 may be positioned adjacent to respective TDECs 106, or they may be positioned over a single larger TDEC 106. Dashed lines indicate the locations of the TDECs 106 and integrated circuit 110 when the electronics assembly 100 is fully assembled.

The heating elements 108 are connected by power leads 500 to a power source, such as the integrated circuit 110 or a switch controlled by the integrated circuit 110. The heating elements 108 may be connected in series for simultaneous operation (as shown), or separately connected for individual operation. Each heating element 108 has an associated temperature sensor 300, each of which is connected by communication leads 502 to a controller (e.g., the integrated circuit 110). The power leads 500 and communication leads 502 may be packaged into the assembly in any suitable manner. For example, the power leads 500 and communication leads 502 may be secured in slots 206 (FIG. 2) that extend into the heat-conductive body 104 to the recesses 122.

The embodiments of FIGS. 3-5, and other embodiments having a temperature sensor, may be operated by using the measured temperature to determine when and how to heat the TDEC 106. For example, a control system (e.g., programming provided in the integrated circuit 110) may operate by:
(a) measuring a first temperature value T1 representing a first operating temperature of the TDEC 106;
(b) determining that the first temperature value T1 does not exceed a first reference temperature value TR1;
(c) passing an electric current through the heating element 108 to generate a first quantity of thermal energy;
(d) passing a first portion of the first quantity of thermal energy from the heating element to the TDEC 106 (e.g., via the first thermal interface 124);
(e) measuring a second temperature value T2 representing a second operating temperature of the TDEC 106;
(f) determining that the second temperature value T2 is not below the first reference temperature value TR1; and
(g) terminating passing the electric current through the heating element 108.
   The process may be operated continuously (i.e., at the clock speed of the system), or it may be operated periodically. The process may, in some cases, only be performed once, at the startup of the system. The process also may be suspended after the initial operation, but performed again upon certain trigger events, such as upon determining that a temperature at the temperature sensor 300 has dropped below a certain value.

The first reference temperature value TR1 may be selected according to various criteria. For example, if the temperature sensor 300 provides a value that is directly representative of the operating temperature of the TDEC 106, then the first reference temperature value TR1 may be selected as the minimum desired operating temperature of the TDEC 106 (e.g., Example 1 might use a first reference temperature value TR1 of 0° C.). However, if the temperature sensor 300 provides a value that is indirectly representative of the operating temperature of the TDEC 106, the first reference temperature value TR1 may be adjusted to account for the difference between the measured temperature value and the actual expected operating temperature of the TDEC 106.

The first reference temperature value TR1 also may be selected to be a value that is different from the minimum operating temperature of the TDEC 106. For example, in some cases, residual heat in the heating element 108 may continue to pass to the TDEC 106 after current has stopped passing through the heating element 108. In this case, the first reference temperature value TR1 may be selected to be below the minimum operating temperature of the TDEC 106, with the understanding that the residual heat will bring the TDEC 106 up to the minimum operating temperature after a short time. Upon reaching the first reference temperature value TR1, the control system may begin operating the TDEC 106 at a reduced efficiency, to help speed up the heating process by using the TDEC 106 to generate heat. Alternatively, the control system may start operating the TDEC 106 after a timer elapses to allow the residual heat to raise the temperature before starting operation. Other alternatives and variations will be apparent to persons of ordinary skill in the art in view of the present disclosure.

It will also be understood that other embodiments (see, e.g., FIGS. 1 and 2) may omit the temperature sensor 300 in the electronics assembly 100. In this case, the control system may detect an ambient temperature at another location, such as atmospheric temperature surrounding the equipment in which the electronics assembly 100 is located, and activate the heating element 108 for a predetermined time selected to sufficiently heat the TDEC 106 to the desired operating temperature from the detected atmospheric temperature. Empirical studies, calculations, or other methods may be used to determine the required operation time.

The control system also may use other feedback to determine whether it is necessary to activate the heating element 108. For example, the integrated circuit 110 may be operated to query the operation or performance level of the TDEC 106, thus giving an indication of whether the TDEC 106 has reached its minimum or desired operating temperature.

When it is determined that the heating element 108 should be activated, the control system may use any methodology to perform such activation. For example, the control system may simply apply continuous direct current to the heating element 108. As another example, the control system may apply current periodically or in a waveform having a variable amplitude. The control system also may be programmed to change the amount of current over time, such as by tapering the current up at the beginning of the heating operation, or tapering the current down as the temperature approaches the desired value. In Example 1, the control system may be configured to heat the TDEC 106 at a rate of at least 20° C. per minute, and may do so by applying a continuous electric current of 10 Watts to 18 Watts, and preferably 14 Watts, to the thick chip film resistor heating element 108.

As noted above, activating the heating element 108 causes the heating element 108 to generate a quantity of thermal energy. This thermal passes by convection to the surrounding parts. A first portion of the thermal energy passes from the heating element 108 to the TDEC 106 by way of the first thermal interface 124. Likewise, a second portion of the generated thermal energy passes from the heating element 108 to the heat-conductive body 104 by way of the second thermal interface 126. The thermal energy passing to the heat-conductive element 104 is dissipated by conduction throughout the heat-conductive element 104. Thus, some of this energy can be directed to the integrated circuit 110 or other components in contact with the heat-conductive body 104. Such energy can potentially impair the operation of, or even damage, the other components. For example, in the arrangement of Example 1, heat generated by the thick film chip resistor heating element 108 can potentially damage the field programmable gate array.

In these situations, unwanted heat transfer to other components can be mitigated or avoided by using less conductive materials at the second and/or third thermal interfaces 126, 128. For example, the second thermal interface 126 may comprise a thermal gap material having a lower thermal conductivity coefficient (e.g., 2 Watts per meter-Kelvin) than other materials, such as thermal grease (e.g., 2 Watts per meter-Kelvin), thermal gel (e.g., 3.5 Watts per meter-Kelvin), or thermally-conductive epoxy (e.g., 1 Watt per meter-Kelvin).

In Example 1, the second thermal interface 126 may comprise a thermal gap material, and the first thermal interface may comprise a thermal grease, a thermal gel or a thermally-conductive epoxy. In this case, the thermal energy generated by the heating element 108 passes to the TDEC 106 and to the heat-conductive body 104, but the amount of thermal energy passing to the heat-conductive body 104 is less than the amount of heat passing to the TDEC 106. This reduces the amount of heat passing to the integrated circuit 110, and prevents adverse effects of such heat.

In other embodiments, a material such as a phase changing polymer may be used at the second thermal interface 126. When heat is applied to a phase changing polymer, at least some of the heat is used to change crystalline content of the polymer to the amorphous state. Such phase changes require application of an amount of latent heat, and during this process the temperature of the crystalline content stays approximately equal. Thus, a phase changing polymer can be used to absorb the portion of the heat energy necessary to overcome the latent heat, and thereby delay or reduce the amount of heat transfer to the other side of the phase changing polymer for a period of time.

While the discussion above generally refers to selecting a material for the second thermal interface 126, it will also be appreciated that the third thermal interface 128 may be selected to reduce heat transfer while the heating element 108 is operating. For example, the third thermal interface 128 may comprise a thermal gap material or a phase changing polymer. However, in such cases the material should be selected to ensure proper heat transfer from the integrated circuit 108 (or other components) to the heat-conductive body 104.

Once the TDEC 106 has reached the desired operating temperature, the control system may proceed to operate the TDEC 106, at which time the TDEC 106 may generate another quantity of thermal energy. The amount of thermal energy generated by the TDEC 106 may be less than the quantity of thermal energy that was used to bring the TDEC 106 to the operating temperature, but this is not strictly required. Thus, regardless of what material is selected for the second thermal interface 126, the material preferably has sufficient thermal conductivity to allow heat transfer away from the TDEC 106 while the TDEC 106 is operating. For example, in Example 1, it may be desirable for the thermal flow path from the high bandwidth memory TDEC 106 to the heat-conducting body 108 to be able to pass 5 Watts during operation of the TDEC 106. Thus the total effective thermal coefficient of the first thermal interface 126, heating element 108 and second thermal interface 128 should be selected to allow such heat transfer.

A control system operating the electronics assembly also take other steps during the process of heating the TDEC 106 to the desired operating temperature. For example, the control system may begin operation of the TDEC 106 before it reaches the final desired operating temperature. In this case, the control system might further operate by:
(h) measuring a third temperature value T2 representing a third operating temperature of the TDEC 106;
(i) determining that the third temperature value T2 is not below a second reference temperature value TR2; and
(j) operating the integrated circuit 110 to communicate with the TDEC 106.
   The second reference temperature value TR2 can be selected to begin operating the TDEC 106 at any desired temperature. For example, if the TDEC 106 has a minimum operating temperature of −20° C., and a fully-operational operating temperature of 0° C., the second reference temperature value TR2 may be selected as −20° C. or any value between −20° C. and 0° C. In this case, the integrated circuit 110 may begin using the TDEC 106 at a reduced rate or efficiency until the TDEC 106 reached the final operating temperature, in order to maximize operation time. Alternatively, the second reference temperature value TR2 may be the same as the first reference temperature value TR1, in which case the integrated circuit 110 will only start communicating with the TDEC 106 when the TDEC 106 reaches the final operating temperature.

This type of control process, and considerations relating to heat transfer, may be applied to embodiments having any type of TDEC 106, such as a memory, a high bandwidth memory (as in Example 1), a crystal oscillator, or an Infiniband/Ethernet interconnect semiconductor/device. The person of ordinary skill in the art will, given the present disclosure, be able to make modifications to address the particular details of each type of TDEC 106.

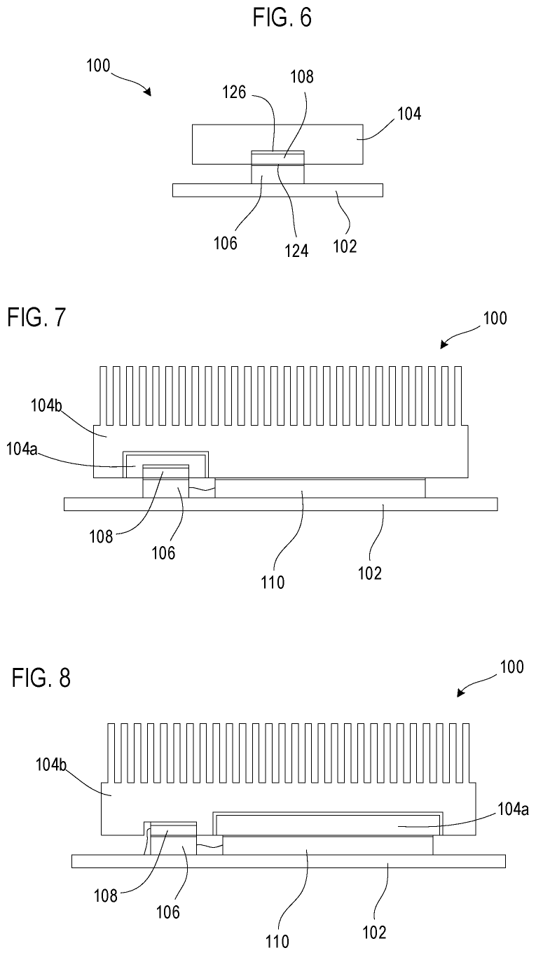

The foregoing examples describe an electronics assembly 100 having a TDEC 106 and integrated circuit 110, which are both in contact with the heat-conductive body 104. It will be understood, however, that the integrated circuit 110 is not required in all cases to be in contact with the heat-conductive body 104. Furthermore, other embodiments may not have an integrated circuit 110 on the substrate 102. An example of such an embodiment is illustrated in FIG. 6. Here, the electronics assembly 100 has a substrate 102, a TDEC 106, a heater 108, and a heat-conductive body 104. The TDEC 106 is thermally connected to the heat-conductive body 104 by a first thermal interface 124, the heater 108, and a second thermal interface 126. One or more temperature sensors (not shown) may also be provided. This embodiment may operate substantially as described above in relation to the other embodiments, with the omission of processes related to the integrated circuit 110.

FIGS. 7 to 10 show various alternative embodiments of heat-conducting bodies 104.

In FIG. 7, the heat-conducting body 104 has a metal plate 104a that is embedded in a heat sink 104b. The heating element 108 is located in recess within the metal plate 104a, as described in relation to FIG. 1, but the metal plate 104a does not extend over the integrated circuit 110. When the heat sink 104b has a lower thermal conductivity coefficient than the metal plate 104a, this provides a measure to prevent excessive heating of the integrated circuit 110 by the heating element 108.

FIG. 8 shows a heat-conducting body having a metal plate 104a embedded in heat sink 104a, with the metal plate 104a extending over the integrated circuit 110, but not over the heating element 108. Like the embodiment of FIG. 7, when the heat sink 104b has a lower thermal conductivity coefficient than the metal plate 104a, this provides a measure to prevent excessive heating of the integrated circuit 110 by the heating element 108.

The embodiments of FIGS. 7 and 8 also could be combined by providing one metal plate 104a over the heating element 108, and another metal plate 104a over the integrated circuit.

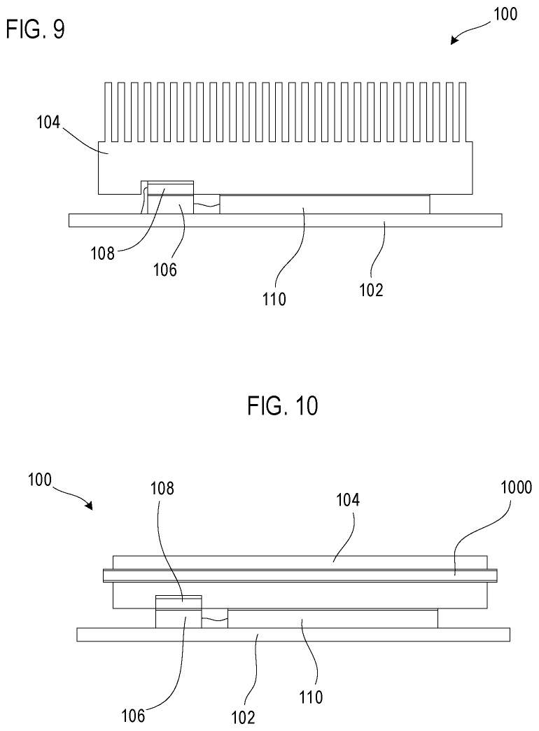

The embodiment of FIG. 9 shows a heat-conducting body 104 formed as a monolithic body, which may be suitable in those cases in which a metal plate 104a is not necessary to distribute heat more rapidly, or if the entire heat-conducting body 104 is formed with a material having a high thermal conductivity coefficient.

FIG. 10 shows another alternative in which the heat-conducting body 104 has a convective cooling passage 1000 passing through it. The convective cooling passage 1000 may comprise, for example, a fluid passage through which a cooling liquid such as a mixture of 70% antifreeze and 30% water, or a specialty chemical such as DURATHERM XLT-120 from Duratherm Extended Life Fluids of Tonowanda, N.Y.

Other alternatives for a heat-conducting body will be apparent to persons of ordinary skill in the art in view of the present disclosure.

An electronics assembly 100 such as the examples herein may be manufactured using any suitable method. For example, the electronics assembly 100 may be manufactured by:
(a) providing a substrate 102 comprising a TDEC 106 (and optionally an integrated circuit 110) attached to the substrate 102;
(b) attaching a heating element 108 to the TDEC 106 by a first thermally conductive path;
(c) attaching a heat-conductive body 104 to the heating element 108 by a second thermally conductive path; and
(d) optionally attaching the heat-conductive body 104 to the integrated circuit 110 by a third thermally conductive path.

The substrate 102, TDEC 106 and integrated circuit 110 may be provided as a pre-assembled unit, with the TDEC 106 and integrated circuit 110 mounted on a printed circuit board substrate 102 with electrical connections already made between the TDEC 106 and integrated circuit 110. Alternatively, the assembly process might involve assembling one or both of the TDEC 106 and integrated circuit 110 (if used) to the substrate 102 and making any necessary electrical connections between the electronic components.

As explained above, the first thermally conductive path may be a first thermal interface 124 comprising a thermal grease, a thermal gel, or a thermally conductive epoxy, and the second thermally conductive path may be a second thermal interface 126 comprising a thermal grease, a thermal gel, a thermal gap material, a thermally conductive epoxy, or a phase changing polymer. The third thermally conductive path, if used, may be a thermal grease, a thermal gel, a thermally conductive epoxy, or possibly a thermal gap material.

The TDEC 106 may comprise a memory, a high bandwidth memory, a crystal oscillator, an Infiniband/Ethernet interconnect semiconductor/device, or other device, and the integrated circuit may comprise a field programmable gate array, a computer processing unit, a graphics processing unit, an Infiniband/Ethernet interconnect semiconductor/device processing unit, or the like.

The method of manufacturing the electronics assembly 100 also may include securing the heating element 108 in a recess in the heat-conductive body 104, and taking steps to ensure that the assembled heating element 108 and heat-conductive body 104 have generally continuous flat lower surface 120. For example, in the case of Example 1, the high bandwidth memory TDEC 106 and the field programmable gate array integrated circuit 110 are pre-installed on a substrate with their upper surfaces lying flat in a common plane. Thus, assembly can be facilitated by ensuring that the heat-conductive body 104 and heating element 108 will conform to this common plane when installed.

In Example 1, the heat-conductive body 104 and heating element 108 can be flattened as follows: First, the thick film chip resistor heating element (e.g., with a beryllium oxide substrate, or an aluminum nitride substrate, gold plated beryllium copper contacts, etc.), is inserted into a recess 122 in the lower surface 120 of the heat-conductive body 104, with an intermediate layer of thermal gel, thermal grease, thermally-conductive epoxy, thermal gap material, phase changing polymer or the like between the heating element 108 and the heat-conductive body 104. Once in place, the heating element 108 is made to be flush with the flat lower surface 120 (if the lower surface 120 is not flat, the heating element 108 and lower surface 120 may be flattened at the same time). The heating element 108 can made flush with the lower surface 120 by machining the heating element 108, such as by sanding, machining, grinding or lapping the heating element 108, and possibly the lower surface 120 as well. When flattened, the heating element 108 and lower surface 120 present a substantially continuous flattened face (some gaps may exist between the heating element 108 and heat-conductive body 104, making the surface partially discontinuous, but still entirely flat). Once flattened, the sub-assembly of the heating element 108 and heat-conductive body 104 is secured to the high bandwidth memory TDEC 106 and the field programmable gate array integrated circuit 110, with an intermediate layer of thermal grease, thermal gel, thermally-conductive epoxy, or the like (installation without any intermediate layer may also be possible in some alternative cases).

The foregoing process is beneficial because it allows the heating element 108 and heat-conductive body to be pre-assembled with a completely flat lower surface. However, it may require permanently attaching the heating element 108 to the heat-conductive body 104 to maintain the flatness of the assembly. This can make disassembly for service impossible.

Alternatively, the heating element 108 can be made flush with the lower surface 120 by separately ensuring that the lower face of the heating element 108 and the lower surface 120 are flat when not assembled together, inserting the heating element 108 into the recess 122, and then providing a mechanism to allow the heating element 108 to move into a position where it is flush with the lower surface 120 once the parts are assembled to the TDEC 106 and integrated circuit 110. For example, the heating element 108 may be loosely placed in the recess 122 with an intermediate layer of thermal gap material, and then this subassembly can be pressed down on the TDEC 106 and integrated circuit 110 to compress the thermal gap material until the heating element 108 and lower surface 120 are lying in the common plane of the TDEC 106 and integrated circuit 110.

In another case, the heating element 108 may be fixed to the TDEC 106 before joining the heat-conductive body 104 to the assembly. This may be useful if the heating element 108 is electrically connected to the TDEC 106 and/or integrated circuit.

Other steps may be added to secure one or more temperature sensors 300 to the assembly. For example, a temperature sensor 300 may be secured inside the recess 122. This can be done, for example, by securing the temperature sensor 300 to the heating element 108 before inserting the heating element 108 into the recess 122, or by separately inserting the temperature sensor 300 into the recess. In other cases, the temperature sensor 300 may be secured to the TDEC 106 before or after assembling the heating element 108 to the TDEC. Other alternatives and variations will be apparent to persons of ordinary skill in the art in view of the present disclosure.

The foregoing description provides numerous examples of electronics assemblies, and methods for making and using electronics assemblies. These examples are intended to be non-limiting. Furthermore, it will be appreciated upon consideration of this disclosure that features of the foregoing examples may be used in other examples. For example, a temperature sensor may be used in any of the shown examples.

1. An electronics assembly comprising:
a substrate;
a heat-conductive body spaced from the substrate;
a temperature dependent electronic component mounted on the substrate; and
a heating element in thermal contact between the temperature dependent electronic component and the heat-conductive body.

2. The electronics assembly of claim 1, wherein the heating element comprises a resistor.

3. The electronics assembly of claim 2, wherein the resistor comprises: a thick film chip resistor with gold plated beryllium copper contacts, a beryllium oxide substrate, or an aluminum nitride substrate.

4. The electronics assembly of claim 1, wherein the heating element has a thermal conductivity of at least 180 watts per meter-Kelvin, and more preferably at least 250 watts per meter-Kelvin.

5. The electronics assembly of claim 1, wherein a portion of the heat-conductive body most proximal to the temperature dependent electronic component has a thermal conductivity coefficient of at least 200-250 Watts per meter-Kelvin, and more preferably at least 400 Watts per meter-Kelvin.

6. The electronics assembly of claim 1, wherein the heating element is electrically isolative.

7. The electronics assembly of claim 1, wherein the heating element is configured to heat the temperature dependent electronic component at a rate of at least 20° C./minute.

8. The electronics assembly of claim 1, further comprising a thermal grease, a thermal gel, or a thermally-conductive epoxy between the heating element and the temperature dependent electronic component.

9. The electronics assembly of claim 1, further comprising a thermal grease, a thermal gel, a thermal gap material or a thermally-conductive epoxy between the heating element and the heat-conductive body.

10. The electronics assembly of claim 1, wherein the substrate extends in a plane, the heat-conductive body extends parallel to the plane and is spaced from the substrate, and the heating element extends parallel to the plane and is positioned between the temperature dependent electronic component and the heat-conductive body.

11. The electronics assembly of claim 10, wherein the heating element has an area parallel to the plane, of 0.2 square inches or less.

12. The electronics assembly of claim 10, wherein the heating element has an area parallel to the plane, of 0.1 square inches or less.

13. The electronics assembly of claim 10, wherein the heating element has a thickness in a direction perpendicular to the plane, of 0.2 inches or less.

14. The electronics assembly of claim 10, wherein the heating element has a thickness in a direction perpendicular to the plane, of 0.1 inches or less.

15. The electronics assembly of claim 1, further comprising an integrated circuit mounted on the substrate and in thermal contact with the heat-conductive body, wherein the temperature dependent electronic component is electrically connected to the integrated circuit.

16. The electronics assembly of claim 15, wherein the integrated circuit comprises a field programmable gate array, a computer processing unit, a graphics processing unit, or an Infiniband/Ethernet interconnect semiconductor/device processing unit.

17. The electronics assembly of claim 15, wherein the temperature dependent electronic component comprises a high bandwidth memory, and the integrated circuit comprises a field programmable gate array.

18. The electronics assembly of claim 17, wherein the high bandwidth memory has a minimum operating temperature of at least 0° C., and the field programmable gate array has a minimum operating temperature of less than −20° C.

19. The electronics assembly of claim 15, wherein the heat-conductive body comprises:
a metal plate adjacent to one or both of the temperature dependent electronic component and the integrated circuit; and
a heat sink joined to the metal plate and at least partially extending from the metal plate away from the substrate;
wherein the metal plate has a higher thermal conductivity coefficient than the heat sink.

20. The electronics assembly of claim 19, wherein the metal plate comprises a copper plate.

21. The electronics assembly of claim 19, further comprising a thermal gel or thermal grease between the metal plate and the heat sink.

22. The electronics assembly of claim 10, wherein the heat-conductive body comprises a surface facing the substrate and a recess extending form the surface away from the substrate, and the heating element is mounted within the recess and the integrated circuit is positioned adjacent to the surface.

23. The electronics assembly of claim 22, further comprising one or more temperature sensors mounted adjacent to the temperature dependent electronic component or the heating element, and preferably within the recess.

24. The electronics assembly of claim 23, further comprising an electric circuit in electrical communication with the one or more temperature sensors, and configured to:
detect a respective detected temperature at each of the one or more temperature sensors;
pass electric current through the heating element to thereby heat the temperature dependent electronic component upon determining that the respective detected temperatures are not above a reference temperature value; and
not pass electric current through the heating element upon determining that the respective detected temperatures are above the reference temperature value.

25. The electronics assembly of claim 22, wherein the surface is a flat surface, and wherein a side of the heating element facing the substrate is coplanar with the flat surface.

26. The electronics assembly of claim 1, wherein the temperature dependent electronic component comprises a memory, a high bandwidth memory, a crystal oscillator or an Infiniband/Ethernet interconnect semiconductor/device.

27. The electronics assembly of claim 1, wherein the temperature dependent electronic component comprises:
a memory having a minimum operating temperature of at least −20° C.;
a high bandwidth memory having a minimum operating temperature of at least 0° C.;
a crystal oscillator having a minimum operating temperature of at least −10° C.; or
an Infiniband/Ethernet interconnect semiconductor/device having a minimum operating temperature of at least −40° C.

28. A method of operating an electronics assembly comprising a substrate, a heat-conductive body, a temperature dependent electronic component mounted on the substrate, and a heating element in thermal contact between the temperature dependent electronic component and the heat-conductive body, the method comprising:
measuring a first temperature value representing a first operating temperature of the temperature dependent electronic component;
determining that the first temperature value does not exceed a first reference temperature value;
passing an electric current through the heating element to generate a first quantity of thermal energy;
passing a first portion of the first quantity of thermal energy from the heating element to the temperature dependent electronic component;
measuring a second temperature value representing a second operating temperature of the temperature dependent electronic component;
determining that the second temperature value is not below the first reference temperature value; and
terminating passing the electric current through the heating element.

29. A method for manufacturing an electronics assembly, the method comprising:
providing a substrate comprising a temperature dependent electronic component attached to the substrate;
attaching a heating element to the temperature dependent electronic component by a first thermally conductive path; and
attaching a heat-conductive body to the heating element by a second thermally conductive path.
